(19) United States
(12) Patent Application Publication
(10) Pub. No.: US 2011/0074514 A1
(43) Pub. Date: Mar. 31, 2011

(54) FREQUENCY MEASUREMENT CIRCUIT AND PLL SYNTHESIZER PROVIDED THEREWITH

(75) Inventor: Masazumi MARUTANI, Yokohama (JP)

(73) Assignee: FUJITSU SEMICONDUCTOR LIMITED, Yokohama (JP)

(21) Appl. No.: 12/886,484

(22) Filed: Sep. 20, 2010

(30) Foreign Application Priority Data
Sep. 28, 2009 (JP) 2009-222075

(51) Int. Cl. H03L 7/02; G01R 23/02; G04F 10/04

(52) U.S. Cl. 331/1 R; 324/76.39; 377/20

(57) ABSTRACT

A frequency measurement circuit includes: a first counter that counts a number of edges of a clock signal; a counter latch circuit that stores a first count value of the first counter in response to a reference edge corresponding to a reference clock; a first delay circuit that includes a plurality of first unit delay circuits coupled in series and receives the clock signal; a plurality of first delay latch circuits that latch a respective output among the plurality of first unit delay circuits; a first edge detection circuit that detects the edge in the first delay circuit based on the outputs of the plurality of first delay latch circuits; and a first calculator that calculates a cycle or a frequency of the clock signal based on the first count value between two reference edges and position information corresponding to a edge detected between the two reference edges.

### CROSS-REFERENCE TO RELATED APPLICATIONS

This application claims the benefit of priority from Japanese Patent Application No. 2009-222075 filed on Sep. 28, 2009, the entire contents of which are incorporated herein by reference.

### BACKGROUND

1. Field

Embodiments discussed herein relate to frequency measurement circuits.

2. Description of Related Art

In wireless communications, such as digital television broadcasting and cellular phone communication, synthesizers, which generate low-noise clocks at high speeds, may be used in order to transmit high frequency signals and to process high-speed data. Such synthesizers include a Phase-Locked Loop (PLL) circuit that generates a high-frequency clock whose phase is synchronized with the reference clock oscillated by a crystal oscillator.

Related art is disclosed, for example, in Japanese Laid-open Patent Publication No. 2002-76886, Japanese Laid-open Patent Publication No. 2007-110370 and Japanese Laid-open Patent Publication No. 2001-16191, as well as non-patent material, R.B.STASZEWSKI, “All-DIGITAL FREQUENCY SYNTHESIZER IN DEEP SUBMICRON CMOS”, section 5.2 “JUST-IN-TIME DCO GAIN CALCULATION”, ISBN: 0-471-77255-0.

### SUMMARY

According to one aspects of the embodiments, a frequency measurement circuit is provided with which includes a first counter that counts a number of edges of a clock signal; a counter latch circuit that stores a fist count value of the first counter in response to a reference edge corresponding to a reference clock; a first delay circuit that includes a plurality of first unit delay circuits coupled in series and receives the clock signal; a plurality of first delay latch circuits that latch a respective output among the plurality of first unit delay circuits in response to the reference edge; a first edge detection circuit that detects the edge in the first delay circuit based on the outputs of the plurality of first delay latch circuits; a first calculator that calculates at least one of a cycle and a frequency of the clock signal based on the first count value between two reference edges and position information corresponding to a edge detected between the two reference edges by the first edge detection circuit.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 illustrates an exemplary PLL synthesizer;

FIG. 2A and FIG. 2B illustrate an exemplary lock-in detection circuit;

FIG. 3 illustrates an exemplary synchronization acquisition;

FIG. 4 illustrates an exemplary PLL synthesizer;

FIG. 5 illustrates an exemplary wave number measurement circuit;

FIG. 6 illustrates an exemplary phase measurement circuit;

FIG. 7 illustrates an exemplary phase measurement circuit;

FIG. 8 illustrates an exemplary unit delay-time measurement circuit;

FIG. 9 illustrates an exemplary operation of a unit delay-time measurement circuit;

FIG. 10 illustrates an exemplary operation of a unit delay-time measurement circuit;

FIG. 11 illustrates an exemplary frequency of an output clock;

FIG. 12 illustrates a control circuit;

FIG. 13A and FIG. 13B illustrate an exemplary voltage-controlled oscillator; and

FIG. 14A, FIG. 14B, and FIG. 14C illustrate an exemplary coarse mode and an exemplary fine control mode.

### DETAILED DESCRIPTION

A PLL synthesizer may include a circuit that detects a lock-in state where frequency acquisition has completed in a PLL synthesizer. The lock-in detection circuit detects the lock-in state in response to phase synchronization between a reference clock and a frequency-divided clock signal. The lock-in detection circuit detects the lock-in state of the PLL synthesizer without detecting a high-speed clock frequency, so that the frequency of an output clock signal generated after the lock-in might not coincide with the target frequency.

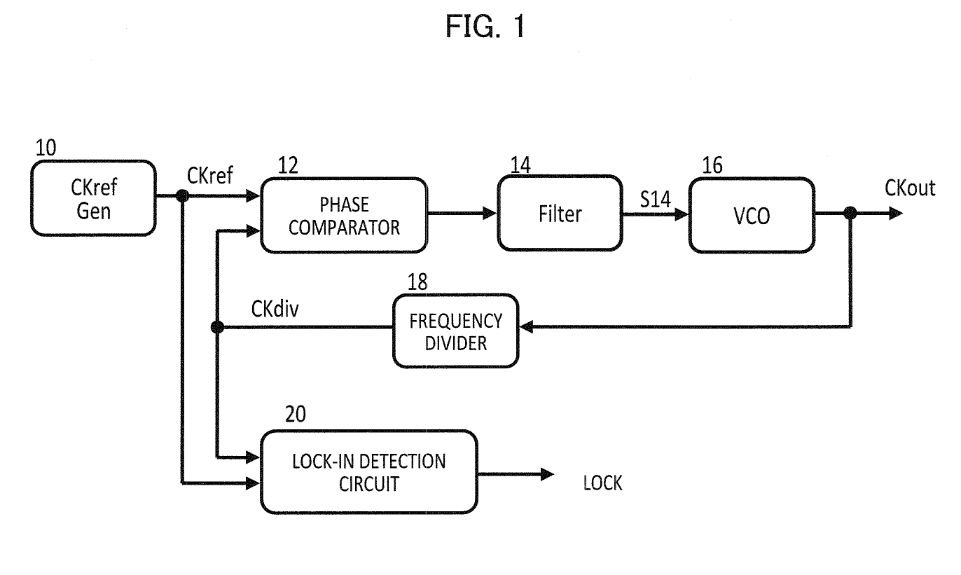

FIG. 1 illustrates an exemplary PLL synthesizer. The PLL synthesizer includes a phase comparator 12, a filter 14, a voltage-controlled oscillator (VCO) 16, and a frequency divider 18. The phase comparator 12 compares the phase of a reference clock signal CKref generated by the reference clock generator 10 with the phase of a frequency-divided clock signal CKdiv and outputs a phase difference signal. The filter 14 removes the high-frequency component of the phase difference signal. The voltage-controlled oscillator (VCO) 16 generates an output clock signal CKout with a certain frequency according to a control voltage S14 corresponding to the phase difference from which the high-frequency component has been removed. The frequency divider 18 divides the frequency of an output clock signal CKout and then outputs a frequency-divided clock signal CKdiv. The frequency-dividing ratio of the frequency divider 18 may be a ratio between the reference clock signal CKref and the output clock signal CKout with a higher frequency than that of the reference clock signal CKref.

The reference clock generator 10 generates a reference clock signal CKref with a known frequency or cycle, such as a clock oscillated by a crystal oscillator. The PLL synthesizer outputs an output clock signal CKout having a frequency obtained by multiplying the reference clock signal CKref by the frequency-dividing ratio and having a phase matched with the phase of the reference clock signal CKref.

The PLL synthesizer uses a feedback loop illustrated in FIG. 1 to synchronize the phase of an output clock signal to the phase of the reference clock signal at the time of a power on or in an active state. The PLL synthesizer includes a lock-in detection circuit 20 which detects phase synchronization and outputs a lock-in signal LOCK. The lock-in detection circuit 20 detects that the phase of frequency-divided clock signal CKdiv and the phase of the reference clock signal CKref are matched with each other.

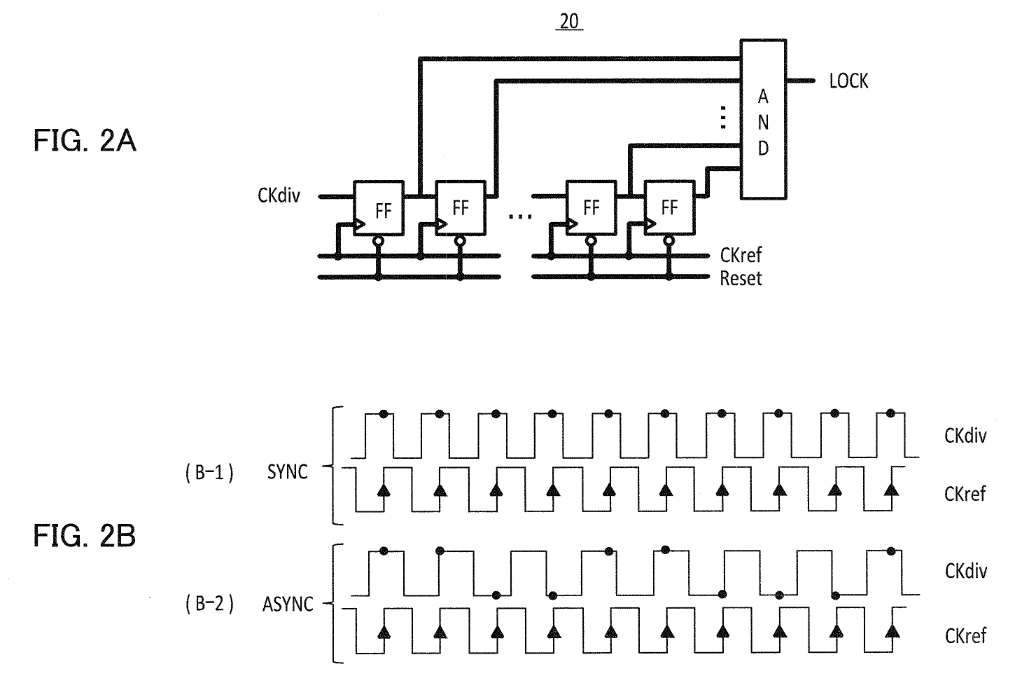

FIG. 2 illustrates an exemplary lock-in detection circuit. The lock-in detection circuit 20 illustrated in FIG. 2A includes a flip-flop FF that latches the frequency-divided clock signal CKdiv in response to the reference clock signal CKref. The data output terminal of the flip-flop FF is coupled to the subsequent data input terminal. The data output terminal of the flip-flop FF is coupled to an AND gate. Then, the AND gate outputs a lock-in signal LOCK.

In the phase synchronization state (B-1) illustrated in FIG. 2B, a frequency-divided clock signal CKdiv which is latched into the flip-flop FF in response to a rising edge of the reference clock signal CKref is at a high level. Therefore, the output of the flip-flop FF becomes a high level, and the AND gate then outputs a lock-in signal LOCK at a high level.

In the phase asynchronous state (B-2), the frequency-divided clock signal CKdiv latched at the rising edge of the reference clock signal CKref is at a high level or a low level. Therefore, the AND gate outputs the lock-in signal LOCK at a low level and then locked off.

In the lock-in detection circuit illustrated in FIG. 2, the time required for detecting a synchronous state and the amount of frequency precision may be traded off. For example, the frequency-divided clock signal CKdiv may have a duty ratio of 50%, a number of stages of flip-flop FF may be 1000, and the reference clock signal CKref may have a frequency of 10 MHz. If outputs of all of the flip-flop FFs are at a high level within the half cycle of the reference clock CKref, a synchronization judgment may be obtained. Since the frequency-divided clock CKdiv takes a time of 1000/10 M=100 μsec to pass through the flip-flop FF, the synchronization judgment may be obtained as long as a periodic error is 0.5/1000=0.0005=0.05% or less every cycle. Thus, the periodic error may be 0.05% or less.

If the output clock CKout is 3 GHz, the periodic error may be 0.05%, 1.5 MHz.

An increase in number of stages of the flip-flop FF leads to a decrease in periodic error but the time for synchronization detection may be prolonged.

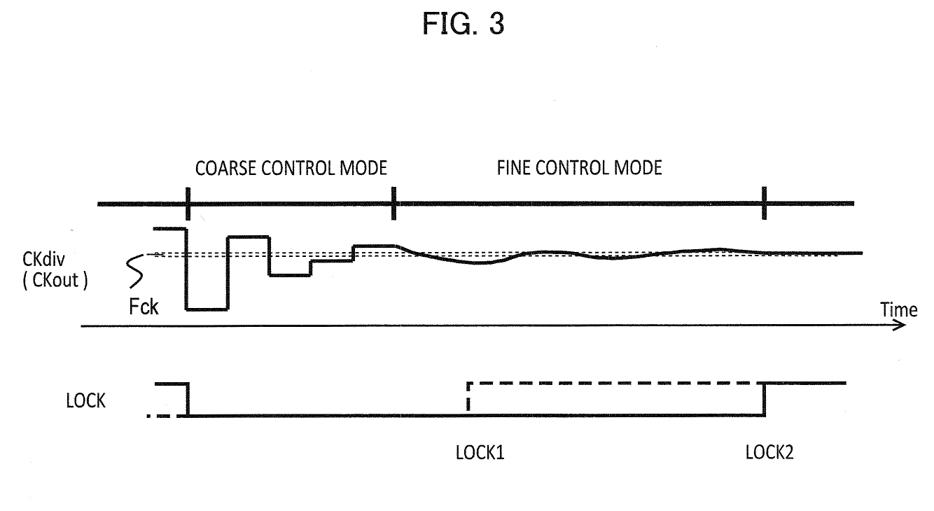

FIG. 3 illustrates an exemplary synchronization acquisition. The synchronization acquisition of the PLL synthesizer illustrated in FIG. 3 includes a coarse control mode in which the control code of the VCO 16 indicating near synchronization state is searched and a fine control mode in which feedback control is performed. In the coarse control mode, the search is performed in a manner in which the frequency control of the voltage-controlled oscillator (VCO) 16 does not depend on a phase difference S14, for example the feedback loop is cut. In the fine control mode, the feedback control is performed in a manner where the frequency control of the VCO 16 depends on the phase difference S14. The locked-in detection circuit might not use such a fine control mode because this detector may not judge a small periodic error which is expected in the fine control mode. Additionally, in the coarse control mode, the search time may be prolonged because the control code is searched depending on the synchronization state, which needs to pass long chain of flip-flop FF's like in FIG. 2A.

In the coarse control mode illustrated in FIG. 3, the control code of the VCO 16 is changed by binary search or the like and the frequency of the frequency-divided clock CKdiv approaches to the target frequency Fck. A lock-in signal LOCK at high level, which is represented as a dashed line in FIG. 3, may be detected due to the limit of accuracy of detecting period, even if the frequency of the frequency-divided clock CKdiv is out of the range of the target frequency Fck, for example, even if the frequency convergence is performing. Therefore, a lock-in signal LOCK represented as a solid line in FIG. 3, may not be obtained.

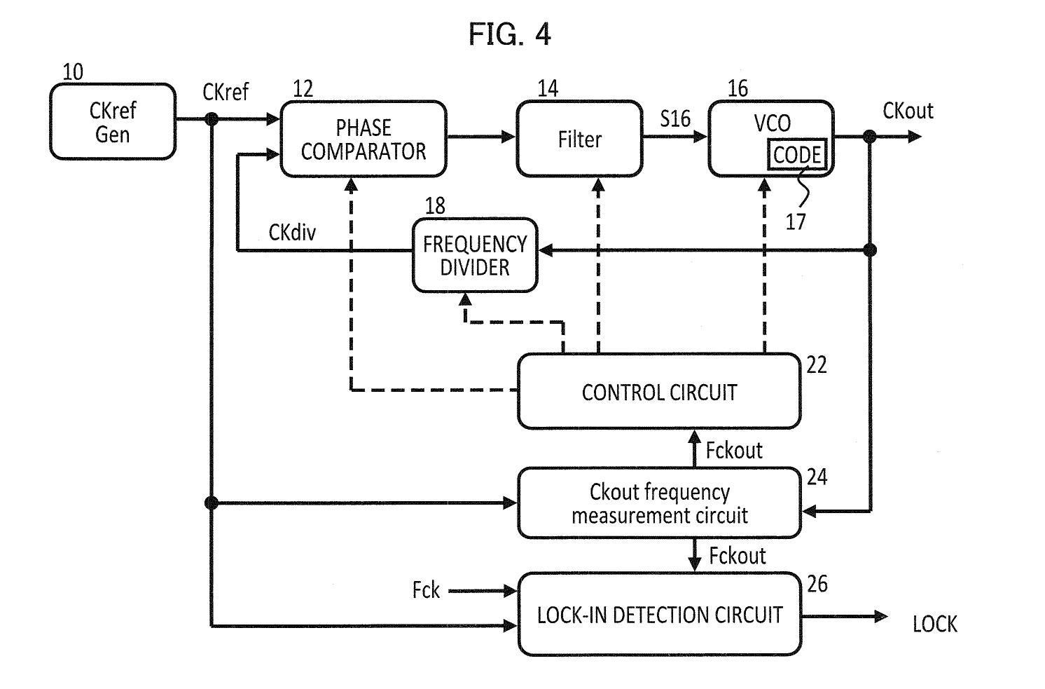

FIG. 4 illustrates an exemplary PLL synthesizer. The PLL synthesizer includes a reference clock generator 10, a phase comparator 12, a Low-pass filter 14, and a voltage-controlled oscillator (VCO) 16, and a frequency divider 18. The VCO 16 includes a control code 17 set in coarse control mode. The PLL synthesizer includes a frequency measurement circuit 24 that measures the cycle or frequency of an output clock signal CKout based on a reference clock signal CKref.

The PLL synthesizer also includes a control circuit 22 that controls the frequency acquisition of a PLL circuit based on the frequency FCKout of an output clock CKout measured by the frequency measurement circuit 24. The control circuit 22 sets a control code 17 in the VCO 16 based on the frequency FCKout measured in coarse control mode. The PLL synthesizer also includes a lock-in detection circuit 26 for detecting that the frequency FCKout of the measured output clock signal CKout entered an acceptable range of the target frequency Fck and for outputting a lock-in signal LOCK. In FIG. 4, the dashed lines represent control signals.

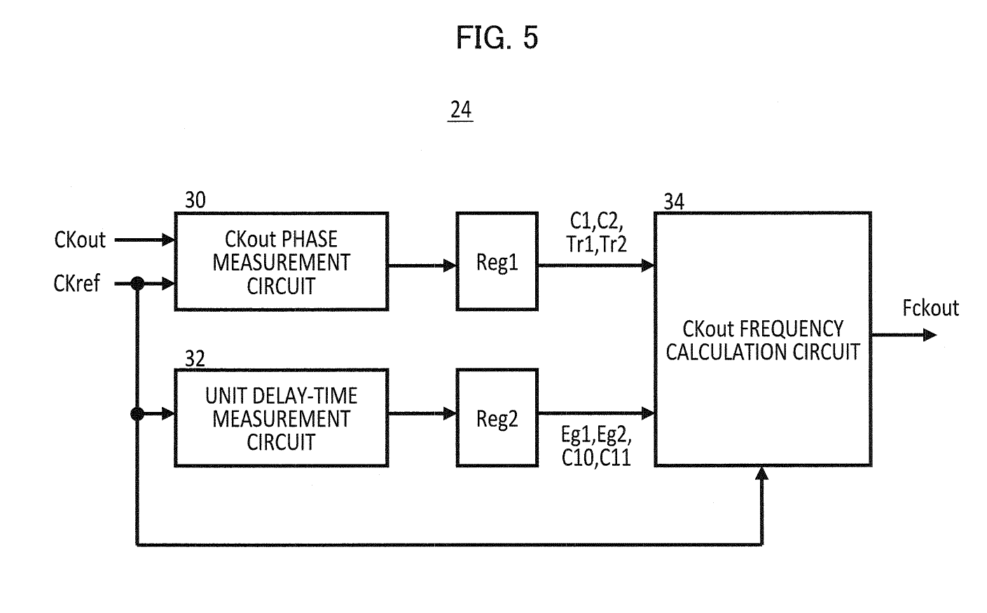

FIG. 5 illustrates a frequency measurement circuit. The frequency measurement circuit 24 includes a phase measurement circuit 30 that measures the phase of an output clock signal CKout based on the reference clock signal CKref, a register Reg1 that latches a value C1, C2, Tr1, or and Tr2 measured by the phase measurement circuit 30, and a frequency calculation circuit 34 that calculates the frequency of the output clock CKout based on the register value. The frequency measurement circuit 24 includes an unit delay-time measurement circuit 32 and a register Reg2. The unit delay-time measurement circuit 32 calculates a delay time of the unit delay circuit in a phase measurement circuit 30 based on the reference clock signal CKref. The register Reg2 latches the calculated value C10, C11, Eg1, or Eg2. The frequency calculation circuit 34 includes a circuit that calculates an unit delay time based on the calculated value C10, C11, Eg1, or Eg2. The delay time of the unit delay circuit may be used for frequency calculation.

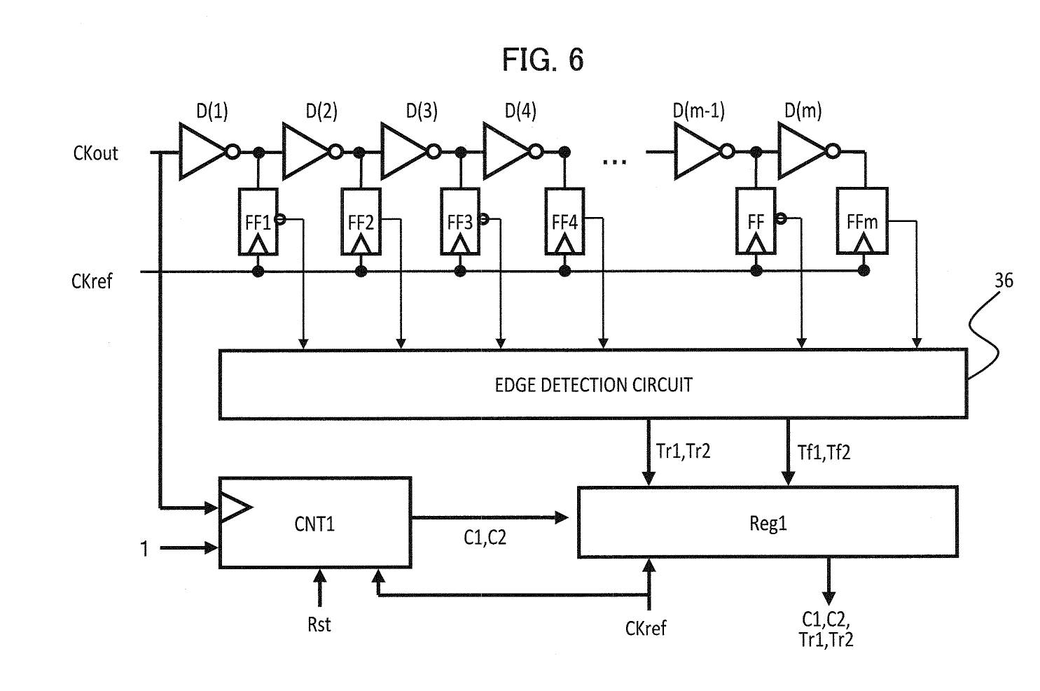

FIG. 6 illustrates an exemplary phase measurement circuit. The phase measurement circuit 30 includes a counter CNT1 that counts either of the number of rising edges or the number of falling edges of output clock signal CKout to be measured. The counter CNT1 is reset to zero (0) in response to a reset signal Rst and counted up by input of “1” (one) in response to the rising edge or the falling edge of the output clock signal CKout. The counter values C1 and C2 of the counter CNT1 are latched into a register Reg1 in response to the reference rising edge or the reference falling edge of the reference clock signal CKref.

The phase measurement circuit 30 includes a delay circuit that delays the output clock signal CKout to be measured. The delay circuit includes a plurality of unit delay circuits D(1) to D(m). The unit delay circuits D(1) to D(m) may include, for example, a CMOS inverter circuit. The number “m” of stages of the delay circuit may be set so that the delay of the delay circuit may be at least longer than the cycle of the output clock CKout and shorter than, for example, the time of one cycle of the reference clock CKref. The delay of the delay circuit may be shorter than, for example, the time of one cycle of the reference clock CKref even when the position of the rising edge or the falling edge of the clock CKout is detected by a plurality of cycles of the reference clock.

The phase measurement circuit 30 includes a plurality of latch circuits FF1 to FFm that respectively latch a plurality of unit delay circuits D(1) to D(m) of the delay circuit in response to the rising edge or the falling edge, for example, the reference clock CKref. The latch circuit may include a flip-flop that latches input data in synchronization with the reference edge of the reference clock. The phase measurement circuit 30 includes an edge detection circuit 36 that detects the position of the rising edge or the falling edge of the output clock signal CKout based on the outputs of a plurality of the unit delay circuits D(1) to D(m) latched by the respective latch circuits FF1 to FFm.

The inverted outputs of the latch circuits FF1, FF3, . . . on the odd-numbered stages and the non-inverted outputs of the latch circuits FF2, FF4, . . . on the even-numbered stages are input into the edge detection circuit 36, respectively. The edge detection circuit 36 makes a comparison between the outputs of the adjacent latch circuits in order to detect the position of the rising edge of the output clock signal CKout, for example, when the output of the (k−1)-th latch circuit FF(k−1) is at a high level “H” and that of k-th latch circuit FFk is at a low level “L”, respectively, or the falling edge of the output clock signal CKout, for example, when the output of the (k−1)-th latch circuit FF(k−1) is at a low level “L” and that of the k-th latch circuit FFk is at a high level “H”, respectively. The register Reg1 latches the rising edge positions Tr1 and Tr2 or the falling edge positions Tf1 and Tf2 detected by the edge detection circuit 36, respectively.

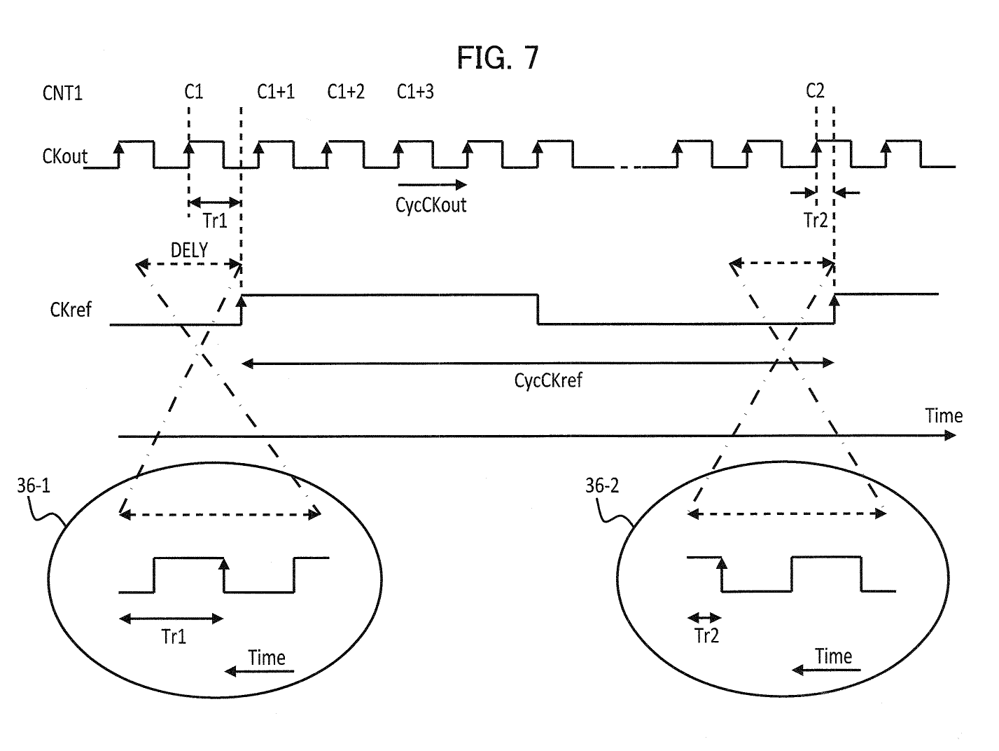

FIG. 7 illustrates an exemplary operation of a phase measurement circuit. The phase measurement circuit 30 calculates the number and phases of the rising or falling edges of the output clock signal CKout between the falling or rising edges of the reference clock signal CKref. For example, the phase measurement circuit may calculate the number and phase of the rising edges of the output clock signal CKout between the rising edges of the reference clock signal CKref. The number of the rising edges of output clock signal CKout is counted by a counter CNT1, and the phase thereof is calculated as an edge position in the delay circuit.

In FIG. 7, the horizontal axis represents a time. The output clock signal CKout to be measured repeats rising and falling. The reference clock signal CKref also repeats rising and falling. The cycle CycCKref of the reference clock signal CKref may be longer than the cycle CycCKout of the output clock signal CKout, and the frequency of the reference clock signal CKref is at a low level. The reference clock CKref may be a known clock, therefore the precise time of CycCKref may be detected.

First, the counter CNT1 and the latch circuits FF1 to FFm are reset in response to a reset signal Rst. The counter CNT1 of the phase measurement circuit 30 counts the number of the rising edges of the output clock signal CKout.

In response to the rising edges of the reference clock signal CKref, the counter values C1 and C2 of the counter CNT1 are latched by the register Reg1.

The rising edge of the output clock signal CKout is input into the first-stage unit delay circuit D(1) among the unit delay circuits D(1) to D(m) and then propagated through these delay circuits according to the delay characteristics of the respective unit delay circuits. The outputs of the respective unit delay circuits D(1) to D(m) are latched to the latch circuits FF1 to FFm in response to the rising edges of the reference clock signal CKref, respectively.

The first rising edge of the reference clock signal CKref appears after a certain delay time corresponding to the Tr1 number of the unit delay circuits D(1) to D(m) from the rising edge of the output clock signal CKout corresponding to the counter value C1. Therefore, waveform 36-1 represents the waveform of the output clock signal CKout propagating through the delay circuits. The waveform 36-1 has a time axis direction opposite to that of the waveform of the output clock signal CKout. The edge detection circuit 36 detects the position where a first high level or a first low level is detected among the output levels of the latch circuits FF1 to FFm and then outputs positional information Tr1. Since the first position of latch circuit FFk where the output of delay circuits FF1 to FF(k−1) is at a high level and output of delay circuit FFk is at a first low level is detected, the different edge positions of the clock signal which may exist at FF(k+1) to FFmmay not be detected. The edge detection circuit may detect TR1 and TR2 in a short time using the counter CNT1 and may detect (CycCKout*(C2−C1)+Tr1+Tr2) using the long chain of flip-flop FF's. The number of stages of the delay circuit may be decreased drastically.

The next rising edge of the reference clock signal CKref corresponds to the count value C2 of the counter CNT1. The next rising edge of the reference clock signal CKref appears after a certain delay corresponding to the Tr2 number of the unit delay circuits D(1) to D(m) from the rising edge of the output clock CKout corresponding to the counter value C2. The waveform 36-2 illustrated in FIG. 7 represents that of the output clock CKout propagating through the delay circuits. The edge detection circuit 36 detects the first position where a high level changes to a low level among the output levels of the latch circuits FF1 to FFm and then outputs positional information Tr2.

The cycle and frequency of the output clock CKout are obtained based on the rising edge of the reference clock signal CKref, such as the counter values C1 and C2 latched by the reference edge, the position information Tr1 and Tr2 in the delay circuit, the delay time Tinv of the unit delay circuit, and the cycle CycCKref of the known reference clock CKref. The cycle CycCKref of the reference clock CKref is calculated by the following equation.

CycCKref=CycCKout*(C2−C1)+(Tr2−Tr1)*Tinv

“C2−C1” represents the count value obtained between the rising edges of the reference clock signal CKref.
“CycCKout” represents the cycle of the output clock CKout.
“Tr2-Tr1” represents the difference of the position information Tr2 and Tr1. “Tinv” represents the delay time.

From the above equation, the cycle CycCKout of the output clock may be represented as follows.

CycCKout={CycCKref−(Tr2−Tr1)*Tinv}/(C2−C1)

The above calculation may be performed by, for example, the frequency calculation circuit 34 illustrated in FIG. 5. The inverse number of the cycle CycCKout of the output clock CKout corresponds to the frequency FCkout.

The CycCKref of the reference clock CKref may be one known in the art. The delay time Tinv of the unit delay circuit may be obtained by the unit delay-time measurement circuit 32 illustrated in FIG. 5. Since the cycle CycCKout of the output clock CKout is divided by the count value (C2−C1) in the above equation, the error corresponds to the time obtained by dividing the unit delay-time Tiny by the count value (C2−C1). If two reference edges of the reference clock signal CKref are not the adjacent rising edges and are set to the rising edges between two or more cycles CycCKref, the error may be decreased as a result of an increase in count value (C2−C1) by two or more times respectively.

In order that phase measurement circuit 30 measure the cycle of output clock CKout at one or multiple cycles of reference clock CKref, a cycle is measured for a short time. The measured cycle and target cycle may be compared and synchronizing detection may be performed in a reduced amount of time.

Since the phase measurement circuit 30 illustrated in FIG. 6 includes the counter CNT1, The number of stages of the unit delay circuits D(1) to D(m) may be the number of stages in which a total delay time from D(1) to D(m) is shorter than the time between two reference edges of the reference clock signal CKref. Even when the phase Tr1 and Tr2 are measured by the signal of one or more cycles of the reference clock CKref, the number of stages of the unit delay circuits may be the number of stages corresponding to the delay time of one or more cycles of the output clock CKout.

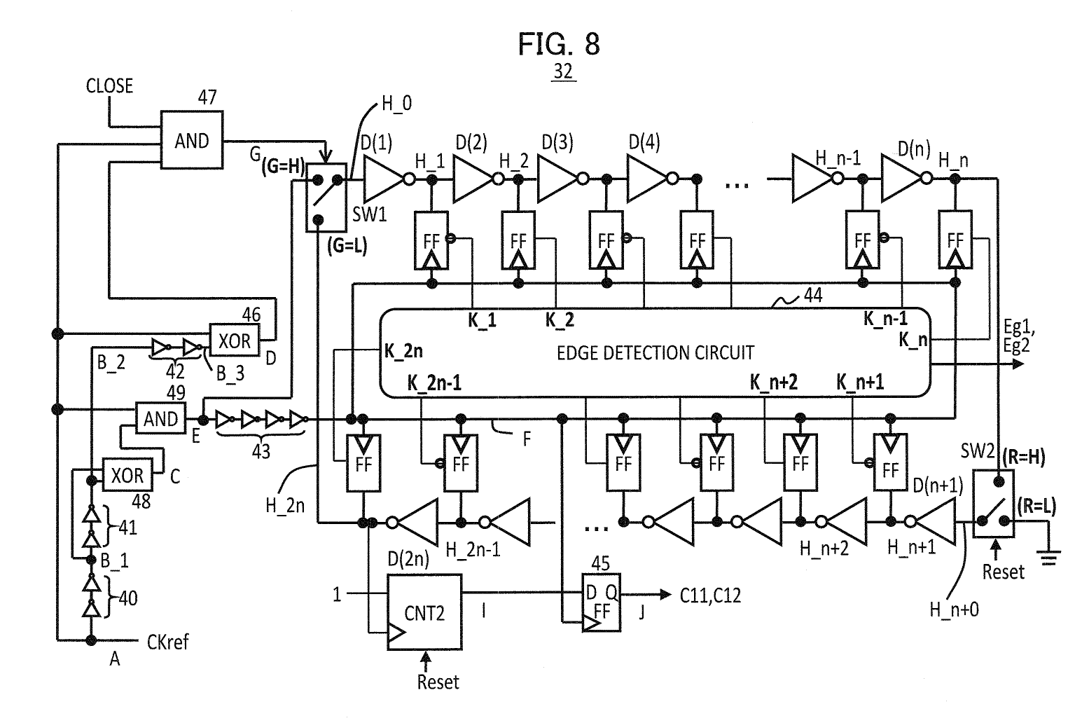

FIG. 8 illustrates an exemplary unit delay-time measurement circuit. The unit delay-time measurement circuit 32 includes a ring delay circuit. The ring circuit includes a plurality of the unit delay circuits D(1) to D(2n) coupled in loop form and receives a one-shot pulse signal E synchronized with the rising edge, for example the reference edge, of the reference clock CKref. The unit delay circuits D(1) to D(2n) of the ring delay circuit may be substantially the same as or similar to the unit delay circuits D(1) to D(m) of the phase measurement circuit 30 illustrated in FIG. 6. The unit delay circuits D(1) to D(2n) of the ring delay circuit and the unit delay circuits D(1) to D(m) of the phase measurement circuit 30 may be formed in the same LSI. The unit delay times of the unit delay circuits may be substantially equal to each other.

The unit delay-time measurement circuit 32 includes a plurality of delay latch circuits FF and an one-shot pulse generator which includes invertors 42, a XOR(exclusive OR) 46, and an AND 47. By two signal inputs A and BXOR 46 generates short period pulses corresponding to rising and falling edges of reference clock A. The period of those pulses is substantially equal to the delay time of invertors 42. The AND 47 generates the one-shot pulses corresponding to only rising edge of reference clock A based on three inputs signals CLOSE, D, and A. The output one-shot pulses from AND 47 may be stopped based on the control signal CLOSE and remains at a low level. The plurality of delay latch circuits FF latch the plurality of unit delay circuits D(1) to D(2n) of the ring delay circuit in response to a latch signal F generated based on the rising edge of the reference clock signal CKref. The latch signal F obtained by delaying a signal E by the delay time of invertors 43 may be output. The signal E may be generated by the reference clock A, invertors 40, invertors 41, XOR 48, and AND 49 in the same way described about invertors 42, XOR 46, and AND 47. The edge detection circuit 44 detects the position of the one-shot pulse signal E corresponding to a latch signal F in the ring delay circuit based on the outputs of the plurality of unit delay circuits latched by the delay latch circuits FF. The number of stages of the invertors 40, 41, 42, and 43 illustrated in FIG. 8 may be arbitrary.

The unit delay-time measurement circuit 32 includes a counter CNT2 that counts a circulation number of the one-shot pulse signal E which circulates around the ring delay circuit. The count value of the counter CNT2 is reset by a reset signal Reset=H and latched by the latch circuit 45 in response to the latch signal F.

The ring delay circuit includes a switch SW1 provided for the input of the fist-stage unit delay circuit D(1). While the signal G is at a high level, the one-shot pulse signal E is input into the first-stage unit delay circuit D(1). While the signal G is at a low level, the one-shot pulse signal E circulates around the ring delay circuit. Switch SW2 is provided for the input of the unit delay circuit D (n+1), while the reset signal Reset is at a high level, a low-level signal is input into the unit delay circuit D(n+1). While the reset signal Reset is at a low level, the one-shot pulse signal E circulates around the ring delay circuit.

In the unit delay-time measurement circuit 32, a one-shot pulse signal E in synchronization with the rising edge of the reference clock signal CKref is input into the ring delay circuit and circulates around the ring delay circuit.

The counter CNT2 counts up every time the one-shot pulse circulates around the output of the unit delay circuit D (2n). The latch circuit 45 latches the count value I of the counter CNT2 in synchronization with the latch signal F generated based on the reference clock CKref. Then, the latched count value I is output as a count value C11 or C12.

The delay latch circuit FF latches the output of each unit delay circuit in synchronization with the latch signal F. The output of latch is inverted on the odd-numbered state and is delivered to the edge detection circuit 44. The output of latch is not inverted on the even-numbered stage and is delivered to the edge detection circuit 44. The edge detection circuit 44 detects the position of the one-shot pulse signal E among outputs signals from 2n latches, and outputs the position information Eg1 and Eg2.

The unit delay-time measurement circuit 32 measures how many stages of the unit delay circuit a one-shot pulse signal E, which is generated based on the rising or falling edge of the reference clock signal CKref, propagates in the ring delay circuit. The counter CNT2 counts the circulation number of the one-shot pulse signal E. To measure a number of unit delay circuit which is equal to a long period of one reference clock CycCKref, using the ring delay circuit instead of the cascaded delay circuit illustrated in FIG. 6 has an advantage. In the latter way, the number of stages of the unit delay circuit becomes large.

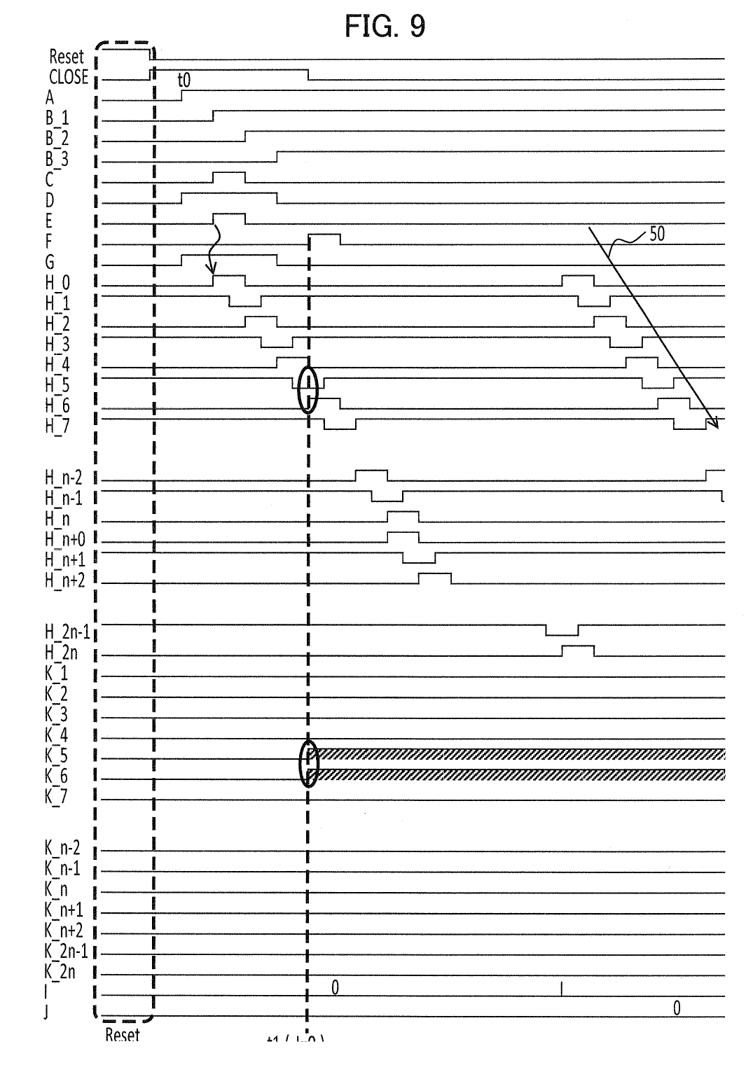

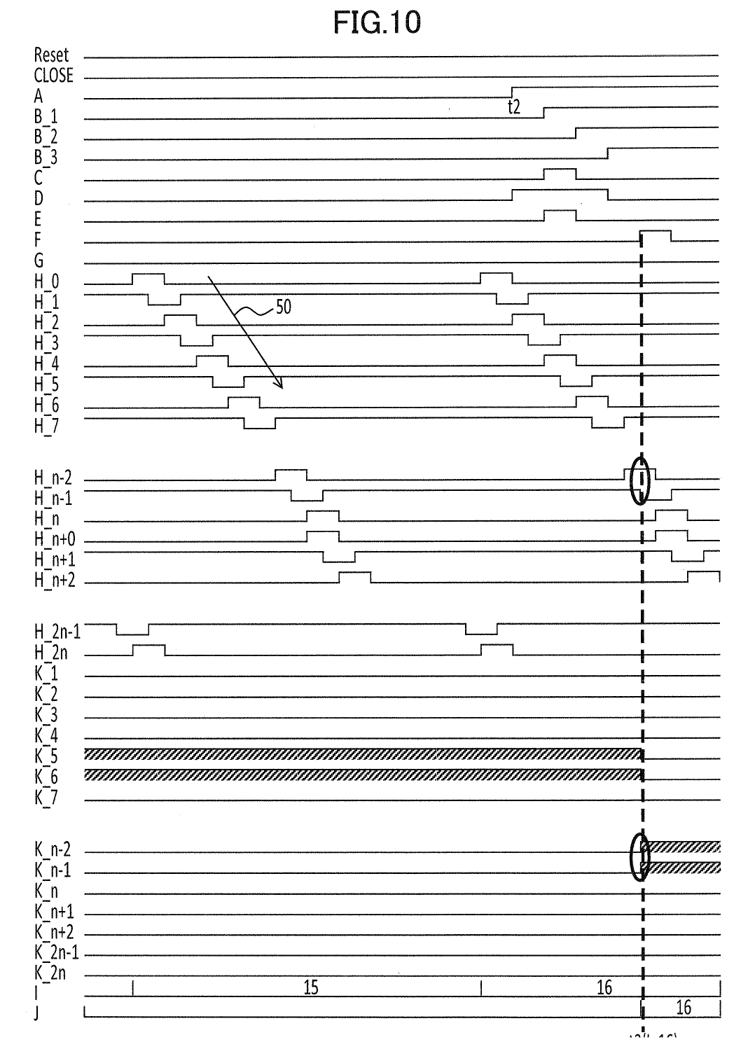

FIG. 9 and FIG. 10 illustrate an exemplary operation of a unit delay-time measurement. The unit delay-time measurement circuit may be the one illustrated in FIG. 8. The operation of the circuit illustrated in FIG. 9 may be performed at the time of starting the measurement. The operation illustrated in FIG. 10 may be performed at the time of completing the measurement. The reset signal Reset turns to a high level and both the counter CNT2 and the delay latch circuit FF are then reset. The low-level reset signal Reset is input into the ring delay circuit via the switch SW2 and the inner state is initialized. At the time of starting the measurement, a closing signal CLOSE is temporarily set to a high level.

At time to, the rising reference clock CKref, for example signal A, passes through the inverter 40 and signal B_1 is input into the inverter 41 and an exclusive OR circuit XOR1. In synchronization with the rising edge of the signal B_1, a one-shot pulse signal E having a pulse width corresponding to the delay time of the inverter 41 is generated. Then, the signal B_1 is output as a signal B_3 from each of the inverter 41 and 42 and then input into an exclusive XOR2. In synchronization with the rising edge of the signal A, a one-shot pulse signal D having a pulse width corresponding to the delay time of each of the inverters 40, 41 and 42 is generated. The output signal G of an AND gate AND may be a one-shot pulse signal having a pulse width substantially equal to that of the signal D.

While signal G is at a high level, the switch SW1 couples the input terminal of the unit delay circuit D(1) to the signal E side and inputs a one-shot pulse signal E into the ring delay circuit. After input of the one-shot pulse signal E, the signal G turns to a low level and the switch SW1 couples the input terminal of the unit delay circuit D(1) to the side of the ring delay circuit. The one-shot pulse signal E propagates and circulates through the unit delay circuit D(1) to D(2n) in the ring delay circuit. Here, the one-shot pulse signal E may be a propagation pulse that propagates through the inside of the ring delay circuit.

At time t1, a latch signal F delayed for the inverter 43 from the one-shot pulse signal E turns to a high level, an output from each of the unit delay circuits D(1) to D(2n) is latched into the delay latch circuit FF. At the odd-numbered stage, an inversion signal is input into the edge detection circuit 44. At the even-numbered stage, a non-inversion signal is input into the edge detection circuit 44.

In response to the input signal, the edge detection circuit 44 detects the position Eg1 of the one-shot pulse signal E in the ring delay circuit at time t1. The latch circuit 45 latches count value I at time t1 to output count value C11.

At time t1 illustrated in FIG. 9, the one-shot pulse signal E propagates to the output H_5 of the unit delay circuit D(5) and H_6 of D(6). Both the inputs K_5 and K_6 of the edge detection circuit 44 turn to a high level. The remaining inputs may turn to a low level. The waveform of the one-shot pulse signal E is input into the edge detection circuit 44 to obtain pulse-position information Eg1. If there are plural outputs at a high level, one number may be selected for Eg1, for example, by selecting the smallest number or the mean value of numbers.

If the one-shot pulse signal E is propagated to the output of the final-stage inverter D(2n) of the ring delay circuit, the counter CNT2 counts up output signal H_2n of a high level. As indicated by the arrow 50 shown in FIG. 9, the one-shot pulse signal repeatedly circulates around the inside of the ring delay circuit.

As illustrated in FIG. 10, after one cycle of the reference clock CKref, a one-shot pulse signal E is generated in response to the rising edge of the reference clock signal CKref at time t2. The generated one-shot pulse signal E may not input to the ring delay circuit through the switch SW1 this time because sigal G is remained at a low level. At time t3, the output of each of the respective unit circuits D(1) to D(2n) is latched into the delay latch circuit FF in response to the latch signal F delayed for the inverter 43 from the signal E and is supplied to the edge detection circuit 44. The edge detection circuit 44 outputs the position Eg2 of the one-shot pulse signal E in the ring delay circuit. The latch circuit 45 latches count value I and outputs count value C12. For example, the position Eg2 may correspond to input K_n-2 or K_n-1, and the count value C12 may be 16. For Eg2 either K_n-2 or K_n-1 is selected by substantially the same method for Eg1.

The frequency calculation circuit illustrated in FIG. 5 calculates delay time Tiny of the unit delay circuit based on the count values C11 and C12 as well as the position information Eg1 and Eg2.

The one-shot pulse signal E, which corresponds to a propagation signal, may be generated at arbitrary times.

Edge positions and count values may be detected in synchronization with the reference edge of the reference clock signal CKref having a known cycle.

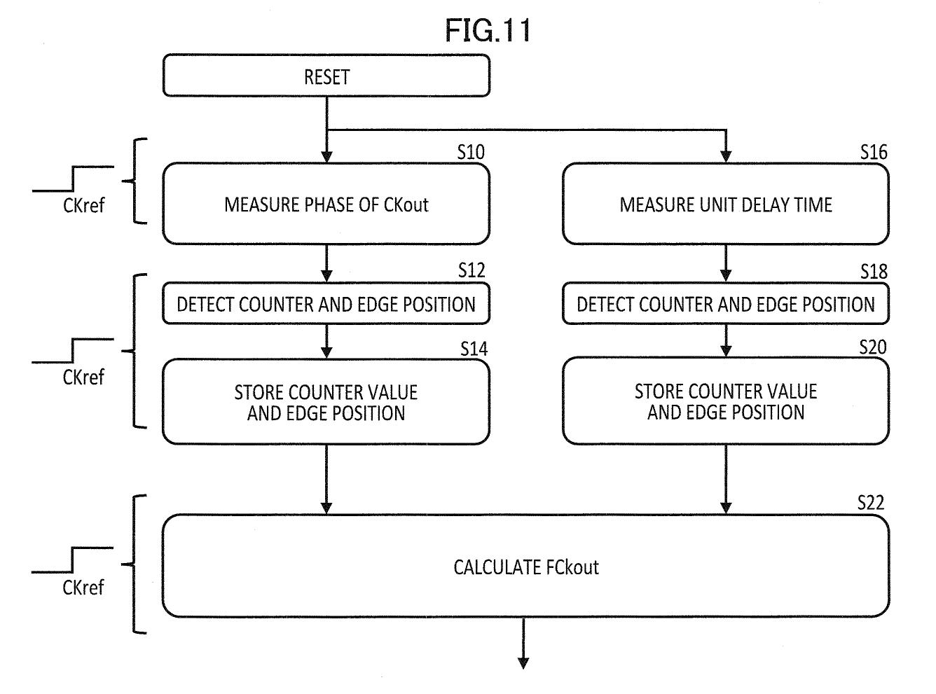

FIG. 11 illustrates an exemplary calculation of an output clock. An output clock CKout from the aforementioned PLL synthesizer may be calculated. In operation S10, the phase of the output clock CKout illustrated in FIG. 6 is measured. In operation S16, for example, the delay time of the unit delay circuit illustrated in FIG. 8 is measured.

In operation S12, the counter values C1 and C2 of the counter CNT1 and the edge positions Tr1 and Tr2 are detected at a timing of the reference edge of the clock signal CKref.

In operation S14, both the counter values C1 and C2 and the edge positions Tr1 and Tr2 are stored in the register Reg1. In operation S18, the counter values C11 and C12 of the counter CNT2 and the edge positions Eg1 and Eg2 are detected at a timing of the latch signal F generated based on the reference edge of the reference clock signal CKref. In operation S20, both the counter values C11 and C12 and the edge positions Eg1 and Eg2 are stored in the register Reg2.

The frequency calculation circuit 34 calculates a unit delay time Tinv using the following equation based on the count values C11 and C12, the edge positions Eg1 and Eg2, and the cycle CycCKref of the reference clock CKref.

CcyCKref={(C12−C11)*2n+(Eg2−Eg1)}*Tinv

The cycle CycCKout of the output clock CKout is calculated from the following formula.

CycCKout={CycCKref−(Tr2−Tr1)*Tinv}/(C2−C1)

The inverse number of the cycle CycCKout turns to the frequency of the output clock CKout.

As an application to measure {C1, C2, Tr1 and Tr2} or {C11, C12, Eg1, and Eg2}, two reference edges are set to several cycles of the reference clock CKref, the count values C2 and C1 are increased while the error of the frequency Tinv/(C2−C1) is decreased. If the count values C2 and C1 become large, the time for calculation of cycles may become long.

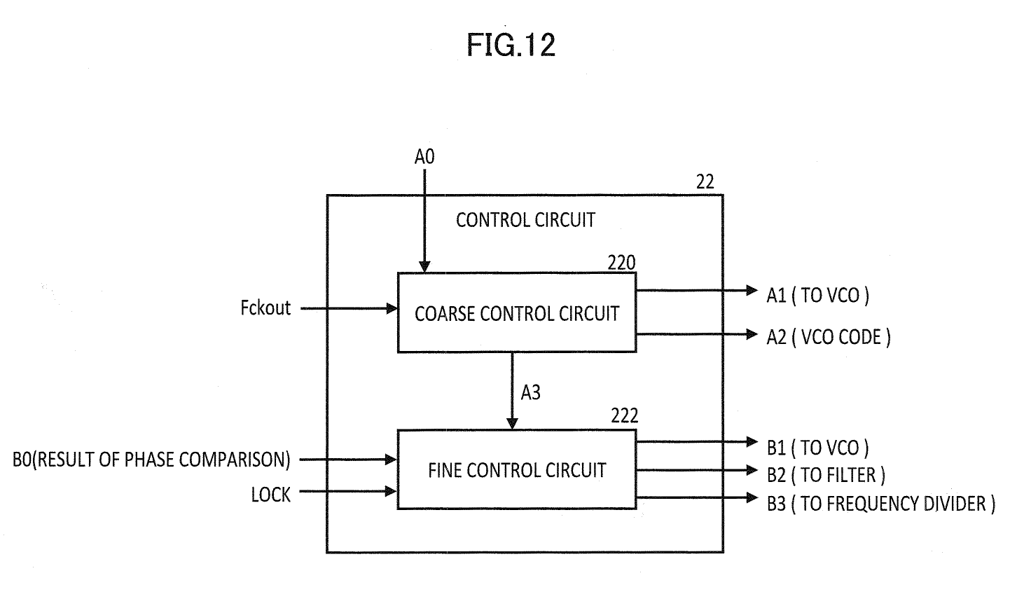

FIG. 12 illustrates an exemplary control circuit. The PLL synthesizer may include a control circuit 22 illustrated in FIG. 12. The control circuit 22 includes a coarse control circuit 220 and a fine control circuit 222. In response to a start signal A0 at the time of frequency change or recovery from sleep mode, the coarse control circuit 220 sets a control voltage Vctrl of the voltage-controlled oscillator VCO16 based on a control signal A1 and sets the control code of the VCO to an initial value based on a control signal A2. The coarse control circuit 220 adjusts the control code of the VCO to the optimal value in response to the control signal A2 based on the measurement result FCKout from the frequency measurement circuit 24 of the output clock CKout.

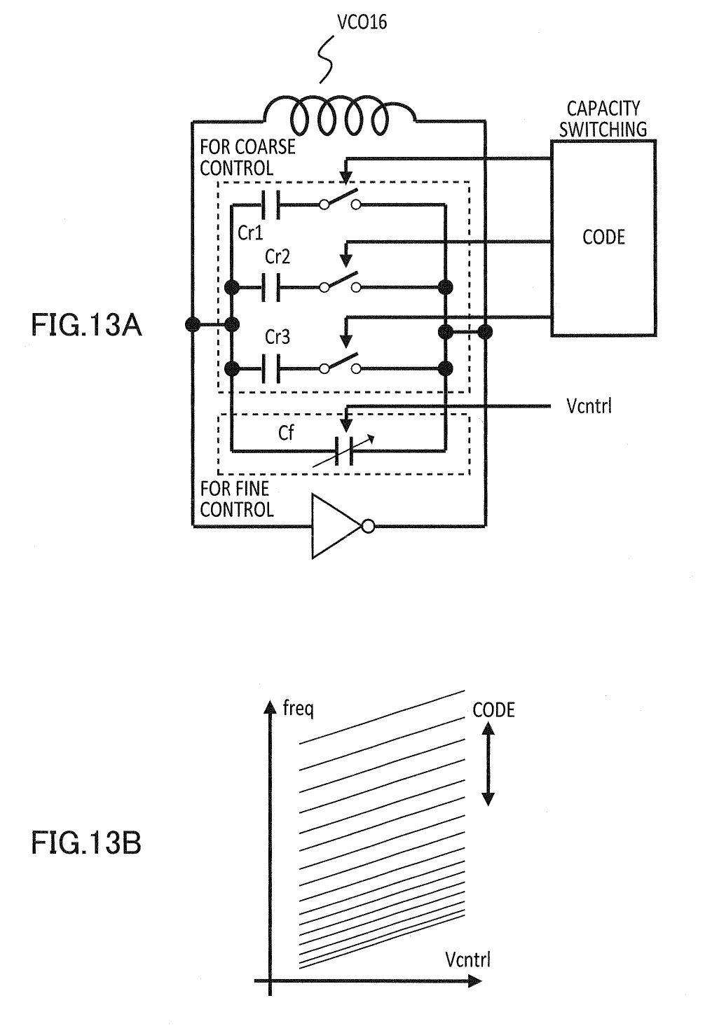

FIG. 13A illustrates an exemplary voltage-controlled oscillator. FIG. 13B illustrates an exemplary control code. The voltage-controlled oscillator VCO16 includes an LC oscillator circuit. The VOC 16 includes coarse control capacitors Cr1, Cr2, and Cr3 and a fine control capacitor Cf. The coarse control capacitors Cr1, Cr2, and Cr3 are coupled to the LC tank of the LC oscillator circuit based on the control code CODE to control to connect or disconnect each coarse control capacitor. The capacity value of the fine control capacitor Cf is controlled depending on the control voltage Vcntrl.

As illustrated in FIG. 13B, the frequency of the VCO16 changes based on the control code CODE and changes based on the control voltage Vcntrl. In the coarse control mode, the frequency is adjusted based on a change in control-code CODE. In the fine control mode, the frequency is adjusted based on a change in control voltage Vcntrl.

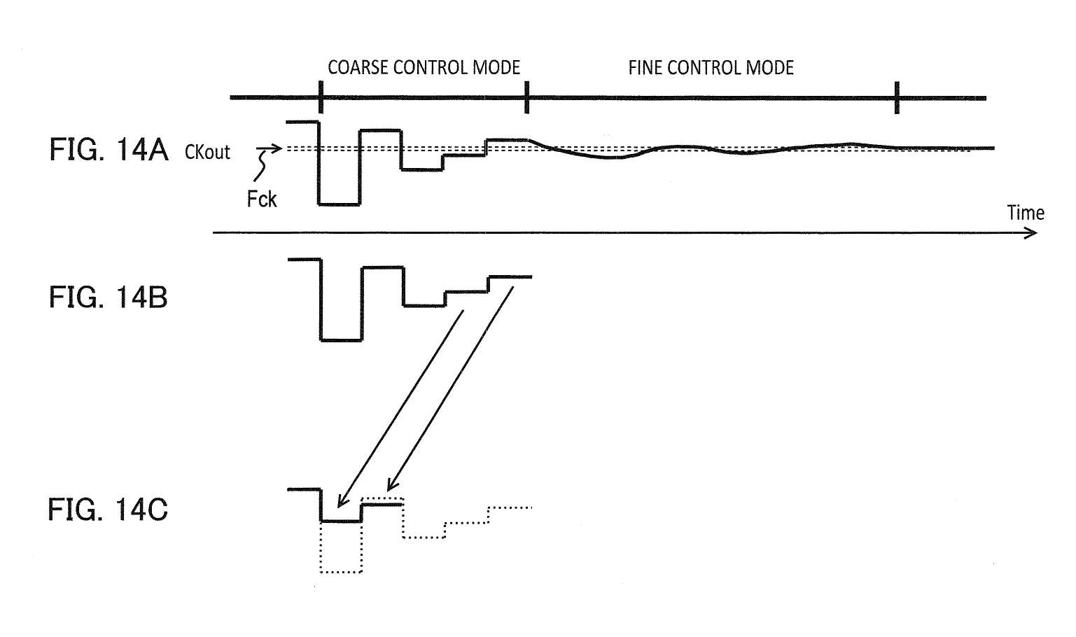

FIGS. 14A, 14B, and 14C illustrate an exemplary coarse control mode and an exemplary fine control mode. FIG. 14A illustrates the output clock CKout of the PLL synthesizer.

In the coarse control mode illustrates in FIG. 3, for example, the time for the search may be prolonged because the control code CODE is detected by a binary search method or the like. In the coarse control mode illustrated in FIG. 14C, a control code is calculated based on the frequency FCKout of the output clock CKout with reference to the arbitrary control code and the coarse control unit 220 is set to the calculated control code within a short amount of time. The time in coarse control mode may be shortened.

The fine control circuit 222 outputs a control signal B1 in response to a coarse control mode termination signal A3 from the coarse control circuit 220. The control voltage Vcntrl of the VCO16 is set to the output signal S16 of the filter 14 based on the control signal B1 and the feedback of the PLL synthesizer is activated. The time constant of the filter 14 is set to be short based on the control signal B2 output from the fine control unit 222 and shorten the response time of the filter 14.

In the fine control mode, a lock-in signal LOCK is output when the lock-in detection circuit 26 illustrated in FIG. 4 detects that the measured frequency FCKout of the output clock CKout matches to the target frequency Fck. The fine control unit 222 refers to the phase comparison result B0 from a phase comparator in response to the lock-in signal LOCK. If a residual phase error, the difference between edges of the reference clock and the output signal from the frequency divider at PHASE COMPARATOR 12, is detected, the frequency-dividing ratio of the frequency divider is temporally changed by control signal B3 and correct phase error. The reset of the frequency divider may be also executed by control signal B3. By these additional controls, the phase may be corrected at a higher speed than that of the phase correction by the feedback control of the PLL synthesizer. The phase synchronization is completed when the fine control unit 222 receives the lock-in signal LOCK and there is no phase error. Therefore, the time constant of the filter 14 may be set to be longer based on the control signal B2, thereby weakening responsiveness and maintaining the lock-in state with better noise suppression for example.

The controls in fine control mode may be performed by other related art technologies.

The PLL synthesizer, which includes a frequency measuring circuit and the unit delay-time measurement circuit, performs high-precision synchronized detection in fine control mode while shortening the control time in coarse control mode. The time to the lock-in of the PLL synthesizer may be shortened, and the power consumption may be reduced. The frequency measurement circuit and the unit delay-time measurement circuit may be activated, for example, when activating the PLL synthesizer or changing frequency. In other cases, the frequency measurement circuit and the unit delay-time measurement circuit may be deactivated.

Aspects of the present invention have now been described in accordance with the above advantages. It will be appreciated that these examples are merely illustrative of the invention. Many variations and modifications will be apparent to those skilled in the art.

1. A frequency measurement circuit, comprising:
a first counter configured to count a number of edges of a clock signal;
a counter latch circuit configured to store a first count value of the first counter in response to a reference edge corresponding to a reference clock signal;
a first delay circuit including a plurality of first unit delay circuits coupled in series, the first delay circuit being configured to receive the clock signal;
a plurality of first delay latch circuits configured to latch a respective output among the plurality of first unit delay circuits in response to the reference edge;
a first edge detection circuit configured to detect the edge in the first delay circuit based on the outputs of the plurality of first delay latch circuits; and
a first calculator configured to calculate at least one of a cycle and a frequency of the clock signal based on the first count value between two reference edges and position information corresponding to an edge detected between the two reference edges by the first edge detection circuit.

2. The frequency measurement circuit according to claim 1, wherein
the first calculator subtracts a value obtained by multiplying a difference between a first position corresponding to a first edge and a second position corresponding to a second edge by a delay time of the first delay circuit from a time between the two reference edges to obtain a first value, the first edge being detected at one reference edge of the two reference edges by the first detection circuit, the second edge being detected at the other reference edge of the two reference edges, and divides the first value with the first count value to obtain the cycle.

3. The frequency measurement circuit according to claim 1, wherein
a delay time from an input of the plurality of first delay circuits coupled in series to an output of the plurality of first delay circuits coupled in series is longer than the cycle of the clock signal and shorter than the time between the two reference edges.

4. The frequency measurement circuit according to claim 1, wherein the first unit delay circuit includes an inverter circuit.

5. The frequency measurement circuit according to claim 1, further comprising,
a unit delay time measuring circuit configured to measure the delay time of the first unit delay circuit,
wherein the unit delay time measuring circuit includes:
a second delay circuit including a plurality of second unit delay circuits coupled in a ring form, the second delay circuit transmitting a propagation pulse;
a plurality of second delay latch circuits configured to latch the outputs of the plurality of second unit delay circuits, respectively, in response to the reference edge;
a second edge detection circuit configured to detect a position of the propagation signal in the second delay circuit based on outputs of the plurality of second delay latch circuits;
a second counter configured to count a number of circulations of the propagation pulse in the ring delay circuit; and
a second calculator configured to calculate a unit delay time of the second unit delay circuit based on a second count value of the second counter between the two reference edges, a position of the propagation pulse detected between the two reference edges, and a time between the two reference edges.

6. The frequency measurement circuit according to claim 5, wherein
the second counter counts the number of circulations after the propagation pulse that is generated based on one of the two reference edges is input into one of the plurality of the second unit delay circuits; and
the second calculator calculates the unit delay time based on the position information of the propagation pulse detected based on an output of the second delay latch circuit in response to the two reference edges, the second count value latched in response to a reference edge subsequent to the one of the two reference edges, and a time between the two reference edges.

7. A PLL synthesizer, comprising:
a frequency measurement circuit;
a phase comparator configured to compare a phase of a frequency-divided clock signal with a phase of a reference clock to detect a phase difference;
a voltage controlled oscillator configured to generate an output clock signal having a frequency according to the phase difference detected; and
a frequency divider configured to frequency-divide the output clock signal to generate the frequency-divided clock, wherein said frequency measurement circuit includes:
a first counter configured to count a number of an edge of the output clock signal;
a counter latch circuit configured to store a first count value of the first counter in response to a reference edge corresponding to a reference clock;
a first delay circuit including a plurality of first unit delay circuits coupled in series, wherein the first delay circuit is configured to receive the output clock signal;
a plurality of first delay latch circuits configured to latch a respective output among the plurality of first unit delay circuits in response to the reference edge;
a first edge detection circuit configured to detect the edge in the first delay circuit based on the outputs of the plurality of first delay latch circuits; and
a first calculator configured to calculate at least one of a cycle and a frequency of the output clock signal based on the first count value between two reference edges and position information corresponding to an edge detected between the two reference edges by the first edge detection circuit.

8. The PLL synthesizer according to claim 7, wherein the voltage controlled oscillator controls the frequency of the output clock signal based on the frequency calculated by at least one of the first calculator and the second calculator in a coarse control mode and controls the frequency of the output clock signal based on the phase difference in a fine control mode.

9. The PLL synthesizer according to claim 8, further comprising:
a lock-in detection circuit that outputs a lock-in signal when the frequency of the output clock signal calculated by the first and second calculators is within a target frequency range in the fine control mode.

10. A unit delay time measuring circuit, comprising:
a delay circuit including a plurality of unit delay circuits coupled in a ring form and configured to transmit a propagation pulse;
a plurality of delay latch circuits configured to latch outputs of said plurality of unit delay circuits, respectively, in response to a reference edge of a reference clock;
an edge detection circuit configured to detect a position of the propagation signal in the delay circuit based on the outputs of the plurality of delay latch circuits;
a counter configured to count a number of circulations of the propagation pulse around said delay circuit; and
a calculator configured to calculate a unit delay time of the unit delay circuit based on a count value of the counter between two reference edges, position information of the propagation pulse detected between the two reference edges by the second edge detection circuit, and a time between the two reference edges.

11. The unit delay time measuring circuit according to claim 10, wherein the counter counts the number of circulations after the propagation pulse that is generated based on one of the two reference edges is input; and
wherein the calculator calculates a unit delay time based on position information of the propagation pulse detected based on the output of the delay latch circuit in response to the two reference edge, a count value of the counter latched in response to the other of the two reference edges and a time between said two reference edges.
